(19) United States
(12) Patent Application Publication
(10) Pub. No.: US 2022/0128905 A1
(43) Pub. Date: Apr. 28, 2022

(54) PHOTORESIST COMPOSITIONS, METHODS FOR FORMING PATTERN USING THE SAME, AND METHODS FOR FABRICATING SEMICONDUCTOR DEVICE USING THE SAME

(71) Applicant: Samsung Electronics Co., Ltd., Suwon-si (KR)

(72) Inventors: SUK KOO HONG, Suwon-si (KR); SUNG AN DO, Hwaseong-si (KR); HONG JOON LEE, Hwaseong-si (KR); SEUNG CHUL KWON, Hwaseong-si (KR); JONG HOON KIM, Hwaseong-si (KR); SIN HAE DO, Busan (KR); JUNG MIN LEE, Suwon-si (KR); EUN SHOO HAN, Changwon-si (KR)

(21) Appl. No.: 17/405,138

(22) Filed: Aug. 18, 2021

(30) Foreign Application Priority Data
Oct. 26, 2020 (KR) 10-2020-0139585

(51) Int. Cl. G03F 7/038; G03F 7/004; C08L 101/02; C08K 5/109

(52) U.S. Cl. CPC G03F 7/0382; C08K 5/109; C08L 101/02; G03F 7/0045

(57) ABSTRACT

Photoresist compositions improving the quality of a photoresist pattern, methods for forming a pattern using the same, and methods for fabricating a semiconductor device using the same are provided. The photoresist composition includes a photosensitive resin, a photoacid generator, a photoacid-labile additive comprising a structure of Formula 1-1, and optionally a solvent:

Ar²—Y-PG² [Formula 1-1]
wherein Ar¹ is a substituted or unsubstituted aromatic ring, Y is an ester group, an oxycarbonyl group, an acetal group, an amide group, or a thioester group, and PG² is a substituted or unsubstituted secondary alkyl group, a substituted or unsubstituted tertiary alkyl group, a substituted or unsubstituted alkoxyalkyl group, a substituted or unsubstituted alkoxy group, or a substituted or unsubstituted alkyloxycarbonyl group.

### CROSS-REFERENCE TO RELATED APPLICATION

This application claims priority from Korean Patent Application No. 10-2020-0139585 filed on Oct. 26, 2020 in the Korean Intellectual Property Office, and all the benefits accruing therefrom under 35 U.S.C. 119, the contents of which in its entirety are herein incorporated by reference.

### BACKGROUND

The present disclosure relates to a photoresist composition, a method for forming a pattern using the same, and a method for fabricating a semiconductor device using the same. More specifically, the present disclosure relates to an extreme ultraviolet (EUV) photoresist composition including a photoacid-labile additive, a method for forming a pattern using the same, and a method for fabricating a semiconductor device using the same.

A photolithography process using a photoresist composition is used to form various patterns included in semiconductor devices. For example, a photoresist pattern may be formed by dividing a photoresist layer into an exposed portion and a non-exposed portion through an exposure process and removing the exposed portion or the non-exposed portion through a developing process. Subsequently, a pattern may be formed by etching a layer using the photoresist pattern as an etching mask.

Meanwhile, as semiconductor devices are gradually highly integrated, critical dimensions of patterns in the semiconductor devices decrease and the aspect ratios thereof increase. Accordingly, photoresist compositions capable of improving distribution and resolution of a photolithography process may be beneficial.

### SUMMARY

Aspects of the present disclosure provide photoresist compositions for improving the quality of a photoresist pattern.

Aspects of the present disclosure provide methods for forming a pattern with improved distribution, resolution and productivity.

Aspects of the present disclosure provide also provide methods for fabricating a semiconductor device with improved reliability and productivity.

However, aspects of the present disclosure are not limited to those set forth herein. The above and other aspects of the present disclosure will become more apparent to one of ordinary skill in the art to which the present disclosure pertains by referencing the detailed description of the present disclosure given below.

According to some embodiments of the present invention, there is provided a photoresist composition comprising a photosensitive resin, a photoacid generator, a photoacid-labile additive comprising a structure of Formula 1-1, and optionally a solvent:

Ar²—Y-PG² [Formula 1-1]

Wherein Ar² is a substituted or unsubstituted aromatic ring, Y is an ester group, an oxycarbonyl group, an acetal group, an amide group, or a thioester group, and PG² is a substituted or unsubstituted secondary alkyl group, a substituted or unsubstituted tertiary alkyl group, a substituted or unsubstituted alkoxyalkyl group, a substituted or unsubstituted alkoxy group, or a substituted or unsubstituted alkyloxycarbonyl group.

According to some embodiments of the present invention, there is provided a photoresist composition comprising a photosensitive resin comprising a structure of Formula 1, a photoacid generator that is configured to generate a photoacid in response to exposure to a light source, a photoacid-labile additive comprising a structure of Formula 2-1 or Formula 2-2, and optionally a solvent:

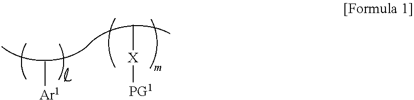

wherein [symbol] and m are each a natural number, Ar¹ is a substituted or unsubstituted aromatic ring, X is a first photoacid-labile group comprising a first hydrophilic functional group that is configured to be exposed by the photoacid, and PG¹ is a first protecting group that is configured to be removed by the photoacid,

EWG-Ar²—Y-PG² [Formula 2-1]

PG²-Y—Ar²—Y—PG² [Formula 2-2]

Wherein Ar² is a substituted or unsubstituted aromatic ring, Y is a second photoacid-labile group comprising a second hydrophilic functional group that is configured to be exposed by the photoacid, PG² is a second protecting group that is configured to be removed by the photoacid, and EWG is an electron withdrawing group.

According to some embodiments of the present invention, there is provided a photoresist composition comprising a photoacid generator configured to generate a photoacid in response to exposure to a light source, a photosensitive resin including a substituted or unsubstituted first aromatic ring, a first photoacid-labile group comprising a first hydrophilic functional group that is configured to be exposed by the photoacid, and a first protecting group that is bonded to the first photoacid-labile group and is configured to be removed by the photoacid, a photoacid-labile additive including a substituted or unsubstituted second aromatic ring, a second photoacid-labile group comprising a second hydrophilic functional group that is configured to be exposed by the photoacid, and a second protecting group that is bonded to the second photoacid-labile group and is configured to be removed by the photoacid, and optionally a solvent, wherein the first hydrophilic functional group and the second hydrophilic functional group are configured to form a non-covalent bond.

According to some embodiments of the present invention, there is provided a method for forming a pattern, which comprises providing a target layer, forming, on the target layer, a photoresist composition including a photosensitive resin, a photoacid generator, a photoacid-labile additive comprising a structure of Formula 1, and optionally a solvent, forming a photoresist pattern by performing an exposure process and a developing process on the photoresist composition, and patterning the target layer using the photoresist pattern as an etching mask:

Ar²—Y-PG² [Formula 1]

Wherein Ar² is a substituted or unsubstituted aromatic ring, Y is an ester group, an oxycarbonyl group, an acetal group, an amide group, or a thioester group, and PG² is a substituted or unsubstituted secondary alkyl group, a substituted or unsubstituted tertiary alkyl group, a substituted or unsubstituted alkoxyalkyl group, a substituted or unsubstituted alkoxy group, or a substituted or unsubstituted alkyloxycarbonyl group.

According to some embodiments of the present invention, there is provided a method for fabricating a semiconductor device, which comprises forming, in a substrate, a plurality of first conductive patterns extending in parallel in a first direction, forming, on the substrate, a plurality of second conductive patterns extending in parallel in a second direction crossing the first direction, forming a plurality of buried contacts connected to the substrate between the plurality of second conductive patterns, forming a pad layer connected to the plurality of buried contacts on the plurality of second conductive patterns and the plurality of buried contacts, and patterning the pad layer to form a plurality of landing pads respectively connected to the plurality of buried contacts, wherein the patterning of the pad layer comprises forming a pattern using a photoresist composition including a photosensitive resin, a photoacid generator, a photoacid-labile additive comprising a structure of Formula 1, and a balance of a solvent:

Ar²—Y—PG² [Formula 1]

Wherein Ar² is a substituted or unsubstituted aromatic ring, Y is an ester group, an oxycarbonyl group, an acetal group, an amide group, or a thioester group, and PG² is a substituted or unsubstituted secondary alkyl group, a substituted or unsubstituted tertiary alkyl group, a substituted or unsubstituted alkoxyalkyl group, a substituted or unsubstituted alkoxy group, or a substituted or unsubstituted alkyloxycarbonyl group.

### BRIEF DESCRIPTION OF DRAWINGS

The above and other aspects and features of the present invention will become more apparent by describing in detail example embodiments thereof with reference to the attached drawings, in which:

FIGS. 1 to 5 are diagrams illustrating a method for forming a pattern according to some embodiments of the present invention.

FIGS. 6 and 7 are diagrams illustrating a method for forming a pattern according to some embodiments of the present invention.

FIGS. 8 to 21 are diagrams illustrating a method for fabricating a semiconductor device according to some embodiments of the present invention.

FIGS. 22 and 23 are electron micrographs showing defects in a semiconductor device according to some embodiments of the present invention.

### DETAILED DESCRIPTION

Hereinafter, a photoresist composition according to example embodiments of the present invention will be described. However, the scope of the present invention is not limited to these embodiments.

The photoresist compositions according to some embodiments of the present invention may include a photosensitive resin, a photoacid generator (PAG), a photoacid-labile additive, and optionally a solvent.

The photoacid generator may generate a photoacid upon exposure to a light source. The light source may be a KrF excimer laser light source, an ArF excimer laser light source, or an extreme ultraviolet (EUV) light source. In some embodiments, the photoacid generator may be in the form of a salt in which a cation is bonded to an anion through electrostatic attraction.

The photoacid generator may include, for example, triphenylsulfonium difluoromethylsulfonate, phthalimidotrifluoromethane sulfonate, dinitrobenzyltosylate, n-decyl disulfone, naphthylimido trifluoromethane sulfonate, diphenyl iodonium triflate, diphenyl iodonium nonaflate, diphenyl iodonium hexafluorophosphate, diphenyl iodonium hexafluoroarsenate, diphenyl iodonium hexafluoroantimonate, diphenyl p-methoxyphenyl sulfonium triflate, diphenyl p-toluenyl sulfonium triflate, diphenyl p-tert-butylphenyl sulfonium triflate, diphenyl p-isobutylphenyl sulfonium triflate, triphenylsulfonium triflate, tris(p-tert-butylphenyl) sulfonium triflate, diphenyl p-methoxyphenyl sulfonium nonaflate, diphenyl p-toluenyl sulfonium nonaflate, diphenyl p-tert-butylphenyl sulfonium nonaflate, diphenyl p-isobutylphenyl sulfonium nonaflate, triphenylsulfonium nonaflate, tris(p-tert-butylphenyl) sulfonium nonaflate, triphenylsulfonium hexafluoroarsenate, triphenylsulfonium hexafluoroantimonate, triphenylsulfonium triflate, and/or dibutylnaphthylsulfonium triflate, but the present invention is not limited thereto. As used herein the term “and/or” includes any and all combinations of one or more of the associated listed items.

In some embodiments, the content of the photoacid generator may be about 0.1 parts by weight to about 0.5 parts by weight with respect to 1 part by weight of the photosensitive resin described later. When the content of the photoacid generator with respect to 1 part by weight of the photosensitive resin is less than about 0.1 parts by weight, the photochemical reaction may be insufficient because the photoacid is not sufficiently generated. When the content of the photoacid generator with respect to 1 part by weight of the photosensitive resin exceeds about 0.5 parts by weight, an outgassing phenomenon, in which byproducts such as hydrogen gas are excessively generated, may occur in a subsequent process (for example, a baking process), thus causing deterioration in the quality of the pattern. In some embodiments, the content of the photoacid generator may be about 0.3 parts by weight to about 0.4 parts by weight with respect to 1 part by weight of the photosensitive resin.

The photosensitive resin may be a polymer that causes a photochemical reaction upon exposure to a light source. The backbone of the photosensitive resin may include a photosensitive resin used for a KrF excimer laser light source, a photosensitive resin used for an ArF excimer laser light source, and/or a hybrid photosensitive resin thereof, but the present invention is not limited thereto.

The photosensitive resin may have a weight average molecular weight (Mw) of about 10,000 to about 600,000. In some embodiments, the photosensitive polymer may have a weight average molecular weight of about 20,000 to about 400,000, or about 30,000 to about 300,000. The weight average molecular weight may be a value measured by gel permeation chromatography (GPC).

In some embodiments, the photosensitive resin may include a substituted or unsubstituted first aromatic ring Ar¹, a first photoacid-labile group X, and a first protecting group PG¹ bonded to the first photoacid-labile group X. For example, the photosensitive resin may be represented by Formula 1-1 below. In Formula 1-1 below, each of [symbol] and m may be a natural number. In some embodiments, [symbol] and m may be different from each other.

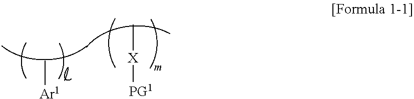

In Formula 1-1 above, Ar¹ represents a substituted or unsubstituted aromatic ring. For example, Ar¹ may represent an aryl group or a heteroaryl group including an at least 5-membered ring. For example, Ar¹ may represent a substituted or unsubstituted phenyl group, a substituted or unsubstituted naphthyl group, or a substituted or unsubstituted thienyl group, but the present invention is not limited thereto. For example, Ar¹ may represent a 4-hydroxyphenyl group.

In Formula 1-1 above, X represents a photoacid-labile group exposing a first hydrophilic functional group X′ by the photoacid. In other words, X represents a photoacid-labile group including a first hydrophilic functional group X′ that is configured to be exposed by a photoacid. The first hydrophilic functional group X′ may, for example, include a hydroxy group, a carboxyl group, a carbonyl group, an amino group, and/or a thiol group, but the present invention is not limited thereto. For example, X may represent an ester group, an oxycarbonyl group, an acetal group, an amide group, or a thioester group. In some embodiments, the first hydrophilic functional group X′ may include a carboxyl group. For example, X may represent an ester group, an amide group, or a thioester group.

In Formula 1-1 above, PG¹ represents a protecting group deprotected from the first hydrophilic functional group X′ by the photoacid. In other words, PG¹ represents a protecting group that is configured to be removed by a photoacid, which is thereby configured to expose the first hydrophilic functional group X′. For example, PG¹ may represent a substituted or unsubstituted secondary alkyl group, a substituted or unsubstituted tertiary alkyl group, a substituted or unsubstituted alkoxyalkyl group, a substituted or unsubstituted alkoxy group, or a substituted or unsubstituted alkyloxycarbonyl group. For example, PG¹ may represent an isopropyl group, a sec-butyl group, a tert-butyl group, a sec-pentyl group, a tert-pentyl group, an alkoxyalkyl group having 1 to 10 carbon atoms, an alkoxy group having 1 to 10 carbon atoms, or an alkyloxycarbonyl group having 1 to 10 carbon atoms, but the present invention is not limited thereto.

For example, the photosensitive resin may be poly(hydroxystyrene-co-propylcyclopentylmethacrylate).

In some embodiments, the photosensitive resin may further include a substituted or unsubstituted heteroalkyl ring CA. For example, the photosensitive resin may be represented by Formula 1-2 below. In Formula 1-2 below, each of [symbol] , m and n may be a natural number. In some embodiments, [symbol] , m and n may be different from each other.

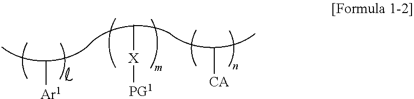

In Formula 1-2 above, CA represents a substituted or unsubstituted heteroalkyl ring. For example, CA may represent a heterocycloalkyl group containing an at least 3-membered ring. For example, CA may represent a substituted or unsubstituted pyrrolidinyl group, a substituted or unsubstituted piperidyl group, or the like, but the present invention is not limited thereto.

In Formula 1-2 above, when n is 2 or more, CA may represent an identical substituted or unsubstituted heteroalkyl ring, or different substituted or unsubstituted heteroalkyl rings.

The photosensitive resin may cause a photochemical reaction, for example, shown in Reaction Scheme 1 below by a light source (e.g., an extreme ultraviolet (EUV) light source).

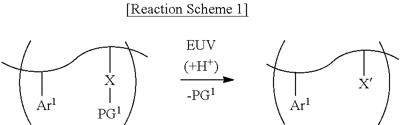

As shown in Reaction Scheme 1 above, the first photoacid-labile group X may expose the first hydrophilic functional group X′ by the photoacid (e.g., H⁺). The first photoacid-labile group X includes the first hydrophilic functional group X′ that is configured to be exposed by the photoacid. In addition, the first protecting group PG¹ may be deprotected or may be removed from the first hydrophilic functional group X′ by the photoacid (e.g., H⁺).

In some embodiments, the content of the photosensitive resin may be about 1 part by weight to about 4 parts by weight with respect to 100 parts by weight of the photoresist composition. When the content of the photosensitive resin with respect to 100 parts by weight of the photoresist composition is less than about 1 part by weight, the light source may not be sufficiently absorbed and thus a photochemical reaction may be insufficient. When the content of the photosensitive resin with respect to 100 parts by weight of the photoresist composition exceeds about 4 parts by weight, the light source may be excessively absorbed and thus the resolution of the photolithography process may decrease.

The photoacid-labile additive may include a substituted or unsubstituted second aromatic ring Ar², a second photoacid-labile group Y, and a second protecting group PG² bonded to the second photoacid-labile group Y. For example, the photosensitive resin may comprise a structure of Formula 2-1 below.

Ar²—Y—PG² [Formula 2-1]

In Formula 2-1 above, Ar² represents a substituted or unsubstituted aromatic ring. For example, Ar² may represent an aryl group or a heteroaryl group including an at least 5-membered ring. For example, Ar² may represent a substituted or unsubstituted phenyl group, a substituted or unsubstituted naphthyl group, or a substituted or unsubstituted thienyl group, but the present invention is not limited thereto. For example, Ar² may represent a p-phenylene group. Ar² may be the same aromatic ring as Ar¹, or may be an aromatic ring different from Ar¹.

In Formula 2-1 above, Y represents a photoacid-labile group exposing the second hydrophilic functional group Y′ by a photoacid. In other words, Y represents a photoacid-labile group including a second hydrophilic functional group Y′ that is configured to be exposed by a photoacid. The second hydrophilic functional group Y′ may, for example, include a hydroxy group, a carboxyl group, a carbonyl group, an amino group, and/or a thiol group, but the present invention is not limited thereto. For example, Y may represent an ester group, an oxycarbonyl group, an acetal group, an amide group, or a thioester group. In some embodiments, the second hydrophilic functional group Y′ may include a hydroxy group and/or a carboxyl group. Y may be the same photoacid-labile group as X, or may be a photoacid-labile group different from X.

In Formula 2-1 above, PG² represents a protecting group deprotected from the second hydrophilic functional group Y′ by a photoacid. In other words, PG² represents a protecting group that is configured to be removed by a photoacid. For example, PG² may represent a substituted or unsubstituted secondary alkyl group, a substituted or unsubstituted tertiary alkyl group, a substituted or unsubstituted alkoxyalkyl group, a substituted or unsubstituted alkoxy group, or a substituted or unsubstituted alkyloxycarbonyl group. For example, PG² may represent an isopropyl group, a sec-butyl group, a tert-butyl group, a sec-pentyl group, a tert-pentyl group, an alkoxyalkyl group having 1 to 10 carbon atoms, an alkoxy group having 1 to 10 carbon atoms, or an alkyloxycarbonyl group having 1 to 10 carbon atoms, but the present invention is not limited thereto. PG² may be the same protecting group as PG¹, or may be a protecting group different from PG¹.

The photoacid-labile additive represented by Formula 2-1 above may cause the photochemical reaction shown in Reaction Scheme 2-1 below by a light source (e.g., an extreme ultraviolet (EUV) light source).

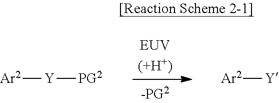

As shown in Reaction Scheme 2-1 above, the second photoacid-labile group Y may expose the second hydrophilic functional group Y′ by a photoacid (e.g., H⁺). The second photoacid-labile group Y includes the second hydrophilic functional group Y′ that is configured to be exposed by a photoacid. In addition, the first protecting group PG² may be deprotected from the second hydrophilic functional group Y′ by the photoacid (e.g., H⁺). In other words, the first protecting group PG² may be configured to be removed by a photoacid.

The photoacid-labile additive may form strong noncovalent interactions with the photosensitive resin as shown in Reaction Scheme 3-1 below, for example, due to exposure to a light source. Reaction Scheme 3-1 below illustrates that each of the first photoacid-labile group X of the photosensitive resin and the second photoacid-labile group Y of the photoacid-labile additive is an ester group.

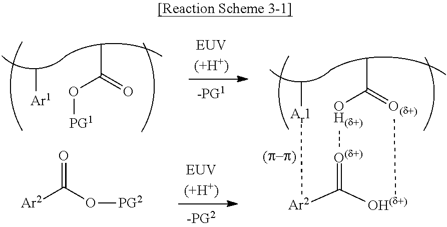

As shown in Reaction Scheme 3-1 above, the first protecting group PG¹ of the photosensitive resin and the second protecting group PG² of the photoacid-labile additive may be removed by the photoacid. When the first protecting group PG¹ and the second protecting group PG² are removed, each of the ester group of the photosensitive resin and the ester group of the photoacid-labile additive may expose a carboxyl group, for example, by action of a photoacid. As a result, the carboxyl group of the photosensitive resin and the carboxyl group of the photoacid-labile additive may form a hydrogen bond. In addition, the first aromatic ring Ar¹ of the photosensitive resin and the second aromatic ring Are of the photoacid-labile additive may form a π bond.

In some embodiments, Formula 2-1 above may represent Formula 2-2 or Formula 2-3 below.

EWG-Ar²—Y—PG² [Formula 2-2]

PG²-Y—Ar²—Y—PG² [Formula 2-3]

In Formula 2-2 below, EWG may represent an electron withdrawing group. For example, EWG may represent a halogen element, an aldehyde group, a ketone group, an ester group, a carboxyl group, a haloalkyl group, a nitrile group, a sulfonyl group, a nitro group, or an ammonium group, but the present invention is not limited thereto. For example, EWG may represent a trifluoromethyl group.

For example, the photoacid-labile additive represented by Formula 2-2 above may be ethoxymethyl 4-(trifluoromethyl)benzoate represented by Formula 3 below.

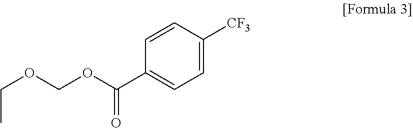 [SMILES: CCOCOC(=O)c1ccc(C(F)(F)F)cc1]

For example, the photoacid-labile additive represented by Formula 2-3 above may be 1,4-di-((tert-butyloxycarbonyl)oxy)-benzene represented by Formula 4 below.

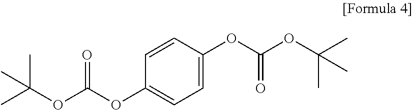 [SMILES: CC(C)(C)OC(=O)Oc1ccc(OC(=O)OC(C)(C)C)cc1]

The photoacid-labile additive represented by Formula 2-2 above may cause the photochemical reaction shown in Reaction Scheme 2-2 below by a light source (e.g., an extreme ultraviolet (EUV) light source).

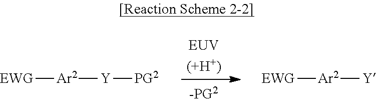

As shown in Reaction Scheme 3-2 below, by the light source, the photoacid-labile additive represented by Formula 2-2 may form a cross-link between the photosensitive resins. Reaction Scheme 3-2 below illustrates that each of the first photoacid-labile group X of the photosensitive resin and the second photoacid-labile group Y of the photoacid-labile additive is an ester group. Reaction Scheme 3-2 below illustrates that the EWG of the photoacid-labile additive is a trifluoromethyl group.

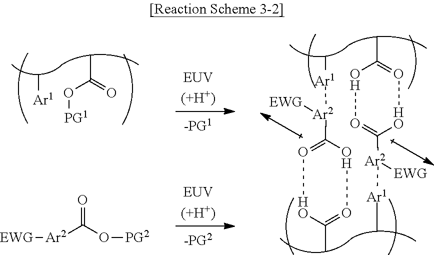

As shown in Reaction Scheme 3-2 above, the ester group of the photoacid-labile additive represented by Formula 2-2 above may expose a carboxyl group by the photoacid (i.e., responsive to the reaction of the photoacid). The carboxyl group of the photoacid-labile additive may form a hydrogen bond with the carboxyl group of the photosensitive resin opposite thereto. In addition, the second aromatic ring Are of the photoacid-labile additive may form a π bond with the first aromatic ring Ar¹ of the photosensitive resin opposite thereto.

As shown in Reaction Scheme 3-2 above, the EWG of the photoacid-labile additive is capable of further enhancing the non-covalent interaction between the photosensitive resin and the photoacid-labile additive by increasing the acidity of the carboxyl group.

The photoacid-labile additive represented by Formula 2-3 above may cause the photochemical reaction shown in Reaction Scheme 2-3 below by a light source (e.g., an extreme ultraviolet (EUV) light source).

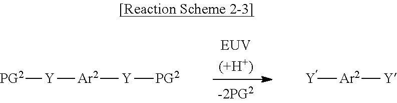

As shown in Reaction Scheme 3-3 below, upon exposure to the light source, the photoacid-labile additive represented by Formula 2-3 may form a cross-link between the photosensitive resins. Reaction Scheme 3-3 below illustrates that the first photoacid-labile group X of the photosensitive resin is an ester group. Reaction Scheme 3-3 below illustrates that the second photoacid-labile group Y of the photoacid-labile additive is an oxycarbonyl group.

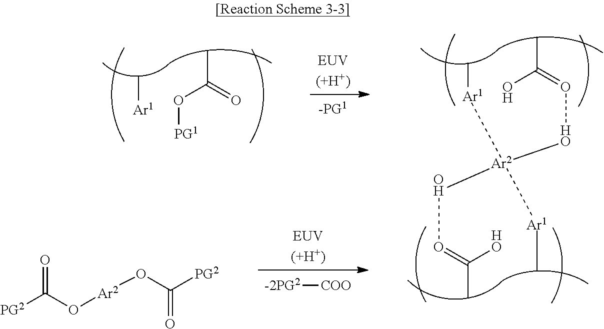

As shown in Reaction Scheme 3-2 above, the oxycarbonyl group of the photoacid-labile additive represented by Formula 2-2 above may expose two hydroxy groups by the photoacid. One of the hydroxy groups of the photoacid-labile additive may form a hydrogen bond with the carboxyl group of the photosensitive resin opposite thereto. The other of the hydroxy groups of the photoacid-labile additive may form a hydrogen bond with the carboxyl group of the photosensitive resin opposite thereto. The second aromatic ring Are of the photoacid-labile additive may form a π bond with the first aromatic ring Ar¹ of the photosensitive resin opposite thereto.

In some embodiments, the content of the photoacid-labile additive may be about 0.01 parts by weight to about 0.15 parts by weight with respect to 1 part by weight of the photosensitive resin. When the content of the photoacid-labile additive with respect to 1 part by weight of the photosensitive resin is less than about 0.01 parts by weight, non-covalent bonding by the light source may be insufficient, and thus the defect rate of the photoresist pattern may increase. When the content of the photoacid-labile additive with respect to 1 part by weight of the photosensitive resin exceeds about 0.15 parts by weight, the photosensitive resin may not sufficiently absorb light emitted from the light source and thus the photochemical reaction may be insufficient.

A solvent may be present in a photoresist composition and may make up the balance of the photoresist composition. In some embodiments, the photoresist composition comprises a photosensitive resin; a photoacid generator; a photoacid-labile additive, and a solvent. The solvent may, for example, include: at least one of ketones such as acetone, methyl ethyl ketone, cyclohexanone, methyl isoamyl ketone, and 2-heptanone; polyhydric alcohols such as ethylene glycol, ethylene glycol monoacetate, diethylene glycol, diethylene glycol monoacetate, propylene glycol, propylene glycol monoacetate, dipropylene glycol, monomethyl ether of dipropylene glycol monoacetate, monoethyl ether, monopropyl ether, monobutyl ether and monophenyl ether, and derivatives thereof; cyclic ethers such as dioxane; esters such as ethyl formate, methyl lactate, ethyl lactate, methyl acetate, ethyl acetate, butyl acetate, methyl pyruvate, methyl acetoacetate, ethyl acetoacetate, ethyl pyruvate, ethyl ethoxy acetate, methyl methoxy propionate, ethyl ethoxypropionate, methyl 2-hydrooxypropionate, ethyl 2-hydroxypropionate, ethyl 2-hydroxy-2-methylpropionate, methyl 2-hydroxy-3-methylbutanoate, 3-methoxybutylacetate and 3-methyl-3-methoxybutyl; or aromatic hydrocarbons such as toluene and xylene, but the present invention is not limited thereto.

The photoresist composition according to some embodiments may further include a sensitizer. The sensitizer may be added to amplify the amount of photons emitted from a light source (e.g., an extreme ultraviolet (EUV) light source) and thereby promote a photochemical reaction.

The sensitizer may include, for example, benzophenone, benzoyl, thiophene, naphthalene, anthracene, phenanthrene, pyrene, coumarin, thioxantone, acetophenone, naphtoquinone, and/or anthraquinone, but the present invention is not limited thereto.

In some embodiments, the content of the sensitizer may be about 0.3 parts by weight to about 0.4 parts by weight with respect to 1 part by weight of the photosensitive resin.

The photoresist composition according to some embodiments may further include a surfactant. The surfactant may be added to improve the ease of application of the photoresist composition. The surfactant may, for example, include an ethylene-glycol-based compound, but the present invention is not limited thereto.

Hereinafter, a method for forming a pattern according to example embodiments will be described with reference to FIGS. 1 to 7.

FIGS. 1 to 5 are diagrams illustrating a method for forming a pattern according to some embodiments of the present invention.

Referring to FIG. 1, a first substrate 10 is provided. Subsequently, a target layer 20, a first mask layer 30, and a first photoresist layer 40 are sequentially formed on the first substrate 10.

The first substrate 10 may be a bulk silicon or silicon-on-insulator (SOI) substrate. The first substrate 10 may be a silicon substrate or may also include other materials such as silicon germanium, gallium arsenide, silicon germanium on insulator (SGOI), indium antimonide, a lead tellurium compound, indium arsenide, indium phosphide, gallium arsenide, or gallium antimonide. Alternatively, the first substrate 10 may be an epitaxial layer formed on a base substrate, or may be a ceramic substrate, a quartz substrate, a glass substrate for a display, or the like.

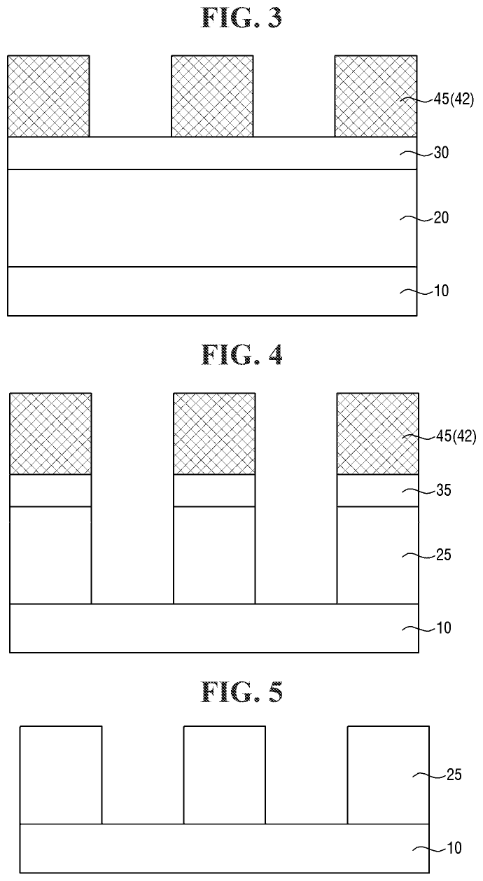

The target layer 20 may be formed on the first substrate 10. The target layer 20 may be a layer in which an image is transferred from a photoresist pattern (45 in FIG. 3) described later and converted into a predetermined target pattern (25 in FIG. 4).

In some embodiments, the target layer 20 may include a conductive material such as a metal, metal nitride, metal silicide or metal silicide nitride layer. In some embodiments, the target layer 20 may include an insulating material such as silicon oxide, silicon nitride, or silicon oxynitride. In some embodiments, the target layer 20 may include a semiconductor material such as polysilicon.

The first mask layer 30 may be formed on the target layer 20. For example, the first mask layer 30 may be formed by being applied on the target layer 20 through a spin-coating process, followed by a baking process. The first mask layer 30 may include, for example, a spin-on hardmask (SOH), but the present invention is not limited thereto.

The first photoresist layer 40 may be formed on the first mask layer 30. The first photoresist layer 40 may be formed on the first mask layer 30 by a coating process such as a spin-coating, dip-coating or spray-coating process. In some embodiments, after the first photoresist layer 40 is applied on the first mask layer 30, a pre-curing process such as a soft-baking process may be performed thereon.

The first photoresist layer 40 may include the photoresist composition. For example, the first photoresist layer 40 may include the photosensitive resin, the photoacid generator, the photoacid-labile additive, and the balance of the solvent.

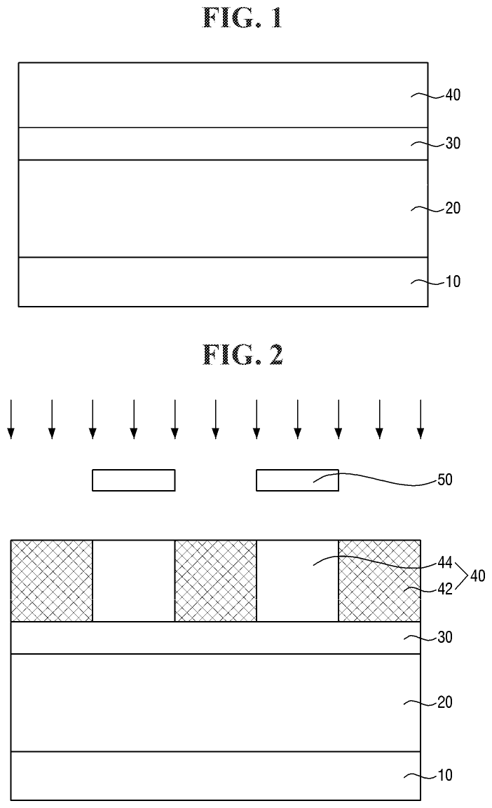

Referring to FIG. 2, an exposure process is performed on the first photoresist layer 40.

The exposure process enables the first photoresist layer 40 to be divided into an exposed portion 42 and a non-exposed portion 44. For example, an exposure mask 50 may be placed on the first photoresist layer 40. When light is irradiated to the top of the exposure mask 50 from a light source, light passing through a transmission portion of the exposure mask 50 is irradiated to a part of the first photoresist layer 40 to form the exposed portion 42. Another part of the first photoresist layer 40 that does not allow light to pass therethrough due to a shielding portion of the exposure mask 50 may form the non-exposed portion 44.

The light source may be a KrF excimer laser light source, an ArF excimer laser light source, or an extreme ultraviolet (EUV) light source. In some embodiments, the light source may be an extreme ultraviolet (EUV) light source.

Referring to FIG. 3, a developing process is performed to form a first photoresist pattern 45.

In some embodiments, the first photoresist pattern 45 may be formed by a negative tone development (NTD) process. For example, the exposed portion 42 may be cured by the exposure process. The cured exposed portion 42 may be left behind after the developing process to form the first photoresist pattern 45.

In some embodiments, after the first photoresist pattern 45 is formed, a curing process such as a hard-baking process may be performed thereon.

Referring to FIG. 4, the target layer 20 is patterned using the first photoresist pattern 45 as an etching mask.

For example, the first mask layer 30 and the target layer 20 may be etched using the first photoresist pattern 45 as an etching mask to form a first mask pattern 35 and a target pattern 25. The etching process may include a dry etching process or a wet etching process depending on a material constituting the target layer 20, an etching selectivity between the first photoresist pattern 45 and the target layer 20, and the like.

Referring to FIG. 5, the first mask pattern 35 and the first photoresist pattern 45 are removed.

The removal of the first mask pattern 35 and the first photoresist pattern 45 may be carried out by, for example, an ashing and/or stripping process.

As a result, the target pattern 25 may be formed on the first substrate 10. When the target layer 20 includes a conductive material, the target pattern 25 may form a predetermined conductive pattern. When the target layer 20 includes an insulating material, the target pattern 25 may form a predetermined insulating pattern. When the target layer 20 includes a semiconductor material, the target pattern 25 may form a predetermined semiconductor pattern.

A negative tone development (NTD) process may be used to form a pattern having a reduced critical dimension. However, as the pattern becomes finer, the negative tone development method has a problem of causing defects such as defects in the cured exposed portion or collapse of the exposed portion.

However, the photoresist composition according to some embodiments may include the photoacid-labile additive, thereby reducing or preventing defects of the exposed portion during the negative tone development process. Specifically, as described with reference to Reaction Scheme 3-1 above, the photoacid-labile additive may form strong noncovalent interactions with the photosensitive resin by the light source. As a result, the bonding force may be increased during the negative tone developing process, and thus a photoresist pattern with improved quality may be provided. In addition, a method for forming a pattern with improved distribution, resolution and productivity may be provided.

In addition, as described with reference to Reaction Scheme 3-2 or 3-3 above, the photoacid-labile additives according to some embodiments may form a cross-link between the photosensitive resins. As a result, a photoresist pattern having further increased quality may be provided in the negative tone development process. In addition, a method for forming a pattern with further improved distribution, resolution and productivity may be provided.

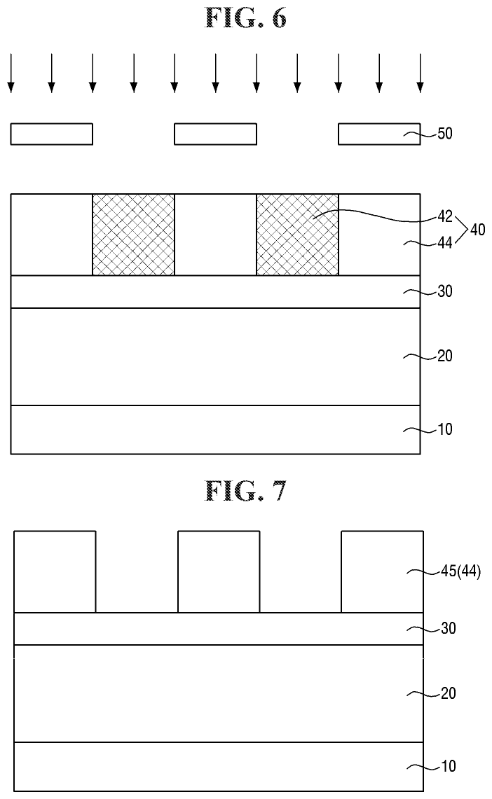

FIGS. 6 and 7 are diagrams illustrating a method for forming a pattern according to some embodiments of the present invention. For simplicity of description, redundant parts of the description made with reference to FIGS. 1 to 5 may be recapitulated or omitted. For reference, FIG. 6 is a diagram showing an intermediate step performed after FIG. 1.

Referring to FIG. 6, an exposure process is performed on the first photoresist layer 40.

The exposure process enables the first photoresist layer 40 to be divided into an exposed portion 42 and a non-exposed portion 44. The exposure process may be similar to that described with reference to FIG. 2 except for the positions of the transmission portion and the shielding portion of the exposure mask 50.

Referring to FIG. 7, a developing process is performed to form a first photoresist pattern 45.

In some embodiments, the first photoresist pattern 45 may be formed by a positive tone development (PTD) process. For example, by the exposure process, the solubility of the exposed portion 42 in a developing solution may be greater than that of the non-exposed portion 44. In the developing process, the exposed portion 42 may be removed by the developing solution. The developing solution may include, for example, a hydrophilic solution such as an alcohol-based solution or a hydroxide-based solution such as tetramethyl ammonium hydroxide (TMAH). The non-exposed portion 44 may be left behind after the developing process to form the first photoresist pattern 45.

Subsequently, the steps described with reference to FIGS. 4 and 5 above may be performed. As a result, the target pattern 25 may be formed on the first substrate 10.

The photoresist compositions according to some embodiments may include the photoacid-labile additive, thereby improving a positive tone development process. Specifically, as described with reference to Reaction Schemes 2-1, 2-2 and 2-3 above, the photoacid-labile additive may expose a plurality of hydrophilic functional groups (the first hydrophilic functional group X′ and the second hydrophilic functional group Y′) by the light source. As a result, the solubility of the exposed portion 42 in the developing solution during the positive tone development process may be further increased and a photoresist pattern having improved quality may be provided.

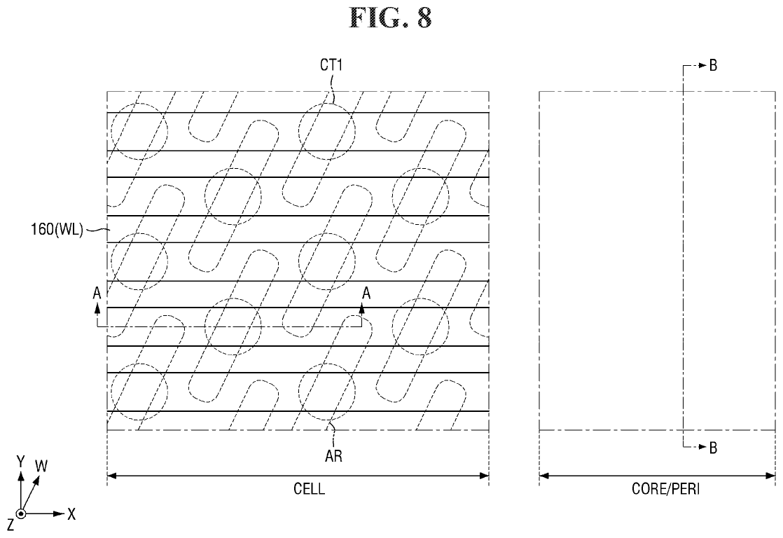

Hereinafter, a method for fabricating a semiconductor device according to example embodiments will be described with reference to FIGS. 8 to 21.

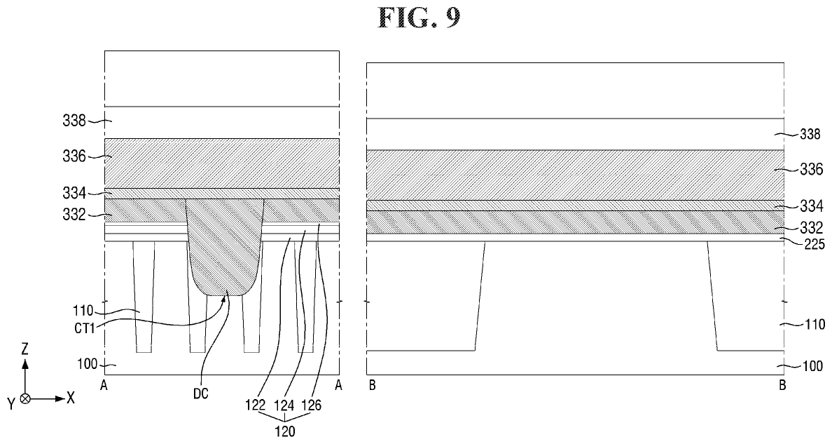

FIGS. 8 to 21 are diagrams illustrating a method for fabricating a semiconductor device according to some embodiments of the present invention. For simplicity of description, redundant parts of the description made with reference to FIGS. 1 to 7 may be recapitulated or omitted. For reference, FIGS. 9, 11, 13, 15, 17 (and 18) and 20 (and 21) are cross-sectional views taken along lines A-A and B-B of FIGS. 8, 10, 12, 14, 16, and 19, respectively.

Referring to FIGS. 8 and 9, a base insulating layer 120, a first conductive layer 332, a direct contact DC, a second conductive layer 334, a third conductive layer 336, and a first capping layer 338 are formed on a second substrate 100 and an element isolation layer 110.

The semiconductor device according to some embodiments may include a cell area CELL and a core/peri area CORE/PERI.

In the cell area CELL, an element isolation layer 110, a base insulating layer 120, a word line WL, a bit line BL, a direct contact DC, a bit line spacer 140, a buried contact BC, a landing pad LP, a capacitor 190, and the like, which will be described later, may be formed to implement semiconductor memory elements on the second substrate 100.

The core/peri area CORE/PERI may be arranged around the cell area CELL. For example, the core/peri area CORE/PERI may surround the cell area CELL. In the core/peri area CORE/PERI, control elements and dummy elements such as a third conductive pattern 230 and a wiring pattern BP, which will be described later, may be formed to control functions of the semiconductor memory elements formed in the cell area CELL. As used herein, an element or region that is “covering” or “surrounding” or “filling” another element or region may completely or partially cover or surround or fill the other element or region.

The second substrate 100 may have a structure in which a base substrate and an epitaxial layer are stacked, but the present invention is not limited thereto. The second substrate 100 may be a silicon substrate, a gallium arsenide substrate, a silicon germanium substrate, or a silicon-on-insulator (SOI) substrate. For example, the second substrate 100 is a silicon substrate in the following description.

The second substrate 100 may include active regions AR. The active region AR may include portions that may include impurities to function as a source/drain region. As the design rule of the semiconductor memory device decreases, the active region AR may be formed in a diagonal bar shape as illustrated in FIG. 8. For example, as shown in FIG. 8, the active region AR may have a bar shape extending in a third direction W different from a first direction X and a second direction Y on a plane on which the first direction X and the second direction Y extend. In some embodiments, the third direction W may form an acute angle with the first direction X. The acute angle may be, for example, 60 degrees, but the present invention is not limited thereto.

The active region AR may be in the form of a plurality of bars extending in directions parallel to each other. In addition, one of a plurality of active regions AR may be arranged such that its center is located close to an end of another active region AR.

The element isolation layer 110 may define the plurality of active regions AR. Although it is shown in FIGS. 8 and 9 that the element isolation layer 110 has an inclined side surface due to the characteristics of the employed process, the present invention is not limited thereto.

The element isolation layer 110 may include silicon oxide and/or silicon nitride, but the present invention is not limited thereto. The element isolation layer 110 may be a single layer made of a single insulating material or a multilayer made of a combination of several kinds of insulating materials.

The word line WL may be elongated in the first direction X across the active regions AR. For example, as shown in FIG. 8, the word line WL may obliquely traverse the active region AR. The word line WL may be interposed between the direct contact DC and the buried contact BC to be described later. A plurality of word lines WL may extend in parallel to each other. For example, the plurality of word lines WL may be formed to be separated at equal intervals and extend in the first direction X.

A first insulating layer 122 and the first conductive layer 332 may be sequentially formed on the second substrate 100 and the element isolation layer 110. In some embodiments, a second insulating layer 124 and a third insulating layer 126 may be further formed on the first insulating layer 122 of the cell area CELL.

Then, a first contact trench CT1 exposing a part of the active region AR may be formed in the second substrate 100 in the cell area CELL. Then, the direct contact DC filling the first contact trench CT1 may be formed. In some embodiments, the first contact trench CT1 may expose the center of the active region AR. Accordingly, the direct contact DC may be connected to the center of the active region AR.

Then, the second conductive layer 334, the third conductive layer 336, and the first capping layer 338 may be sequentially formed on the first conductive layer 332 and the direct contact DC.

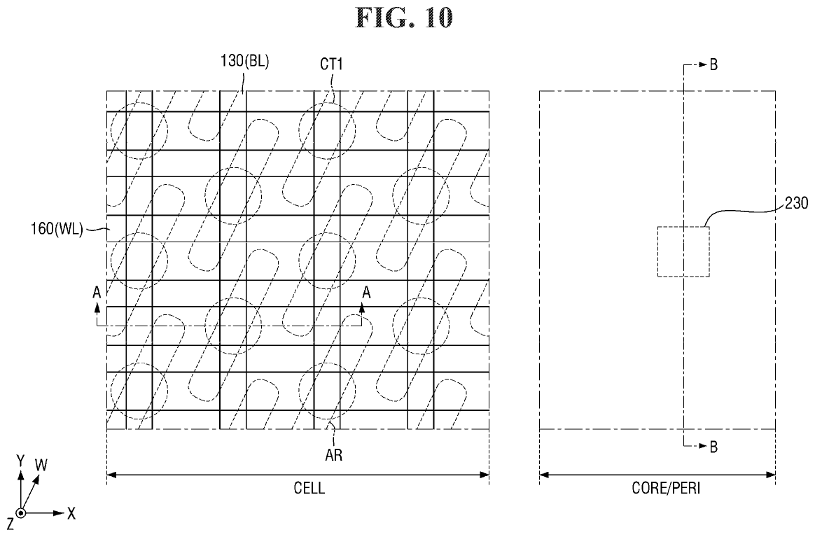

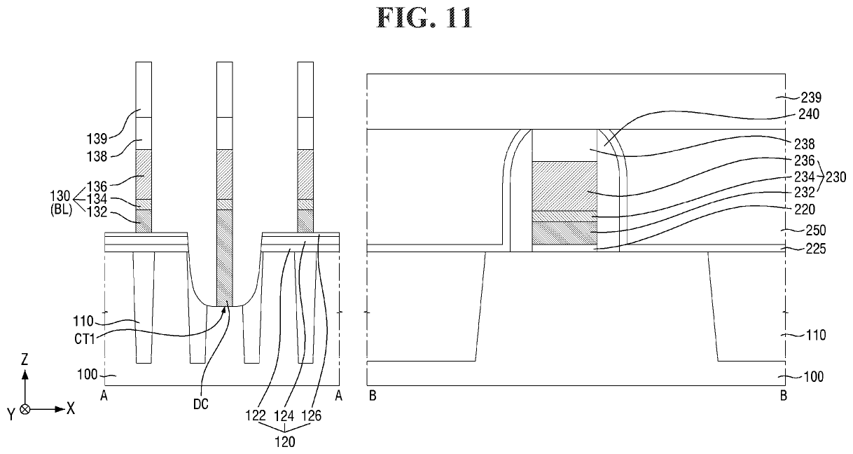

Referring to FIGS. 10 and 11, the first conductive layer 332, the direct contact DC, the second conductive layer 334, the third conductive layer 336, and the first capping layer 338 are patterned.

Accordingly, the second conductive pattern 130 (or bit line BL) and the first bit line capping pattern 138 elongated in the second direction Y may be formed on the second substrate 100 in the cell area CELL. In some embodiments, the second conductive pattern 130 may include three layers (i.e., 132, 134, and 136), which are portions of the first conductive layer 332, the second conductive layer 334, and the third conductive layer 336.

The bit line BL may be formed on the second substrate 100, the element isolation layer 110, and the base insulating layer 120. The bit line BL may be elongated in the second direction Y to traverse the active region AR and the word line WL. For example, the bit line BL may traverse the active region AR obliquely and traverse the word line WL vertically. A plurality of bit lines BL may extend in parallel to each other. For example, the plurality of bit lines BL may be formed to be separated at equal intervals and extend in the second direction Y.

In addition, the gate dielectric layer 220, the third conductive pattern 230, and the gate capping pattern 238 may be formed on the second substrate 100 in the core/peri area CORE/PERI. In some embodiments, the gate space 240, the first liner layer 225, and the second interlayer insulating layer 250 may be further formed on the side surface of the third conductive pattern 230. In some embodiments, the third conductive pattern 230 may include three layers (i.e., 232, 234, and 236), which are portions of the first conductive layer 332, the second conductive layer 334, and the third conductive layer 336.

In some embodiments, the second bit line capping pattern 139 and the third interlayer insulating layer 239 may be further formed. The second bit line capping pattern 139 may extend along the top surface of the first bit line capping pattern 138. The third interlayer insulating layer 239 may extend along the top surface of the gate capping pattern 238 and the top surface of the second interlayer insulating layer 250.

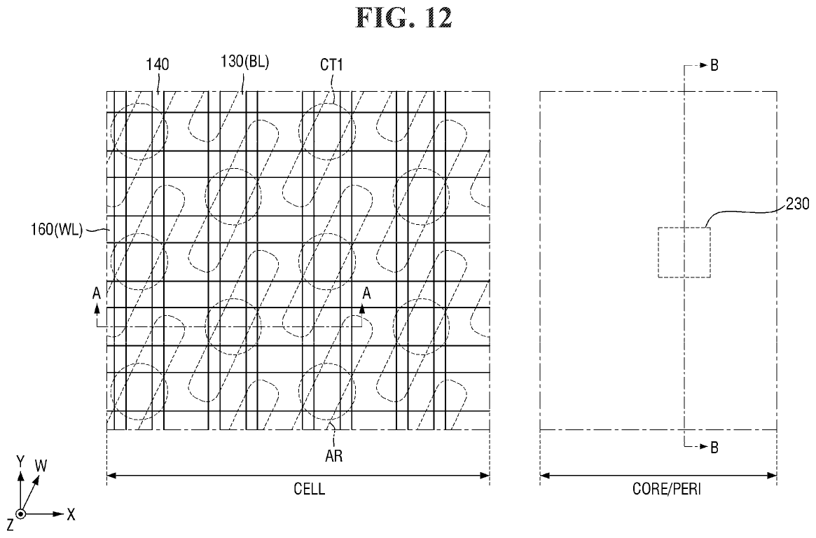

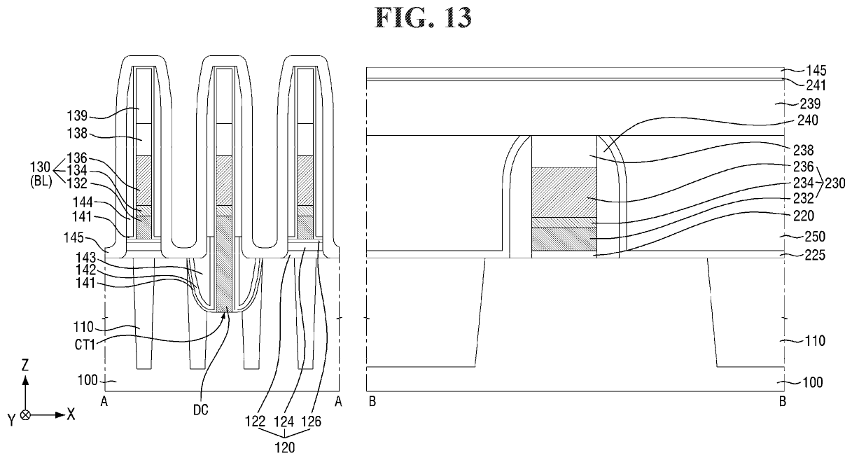

Referring to FIGS. 12 and 13, the bit line spacer 140 is formed on the side surface of the bit line BL.

For example, the bit line spacer 140 may be formed to extend along the side surface of the direct contact DC, the side surface of the second conductive pattern 130, the side surface of the first bit line capping pattern 138, the side and top surfaces of the second bit line capping pattern 139.

In some embodiments, the bit line spacer 140 may include the first spacer 141, the second spacer 142, the third spacer 143, the fourth spacer 144, and the fifth spacer 145.

In some embodiments, the second liner layer 241 may be further formed on the third interlayer insulating layer 239 in the core/peri area CORE/PERI. In some embodiments, the first spacer 141 and the second liner layer 241 may be formed at the same level from the second substrate 100.

In some embodiments, the fifth spacer 145 may extend along the top surface of the second liner layer 241.

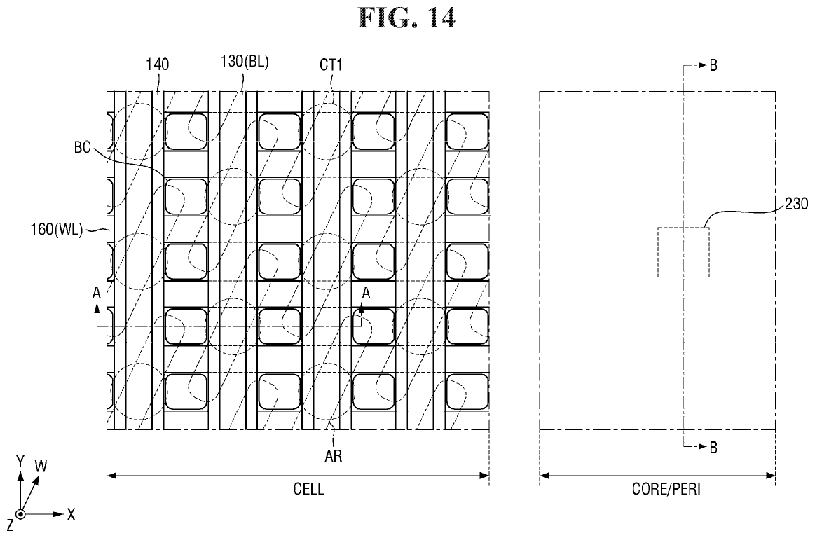

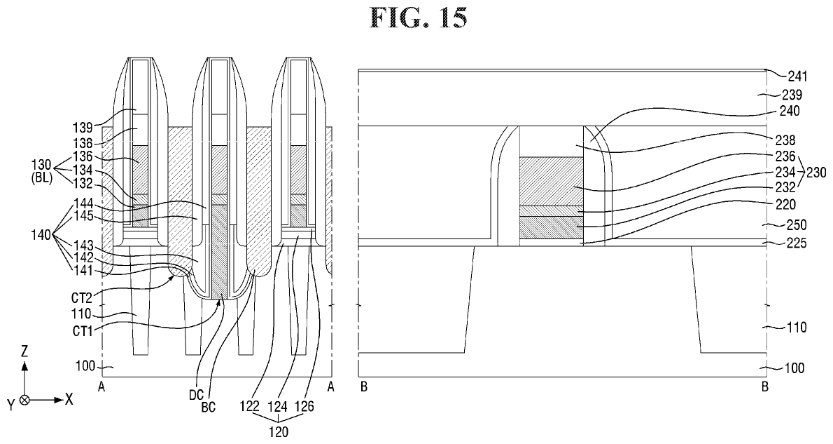

Referring to FIGS. 14 and 15, the buried contact BC is formed on the second substrate 100 and the element isolation layer 110.

For example, a second contact trench CT2 exposing a part of the active region AR may be formed in the second substrate 100 in the cell area CELL. Next, the buried contact BC filling the second contact trench CT2 may be formed. In some embodiments, two second contact trenches CT2 may expose opposing ends of each active region AR, respectively. Accordingly, two buried contacts BC may be connected to opposing ends of the active region AR, respectively.

The buried contact BC may be formed on the side surface of the bit line BL. Further, the buried contact BC may be spaced apart from the bit line BL by the bit line spacer 140. For example, the buried contact BC may extend along the side surface of the bit line spacer 140 as shown in FIG. 3. A plurality of buried contacts BC arranged along the first direction X may be separated from each other by the bit line BL and the bit line spacer 140 elongated in the second direction Y.

The buried contacts BC may form a plurality of isolated regions separated from each other. For example, as shown in FIG. 14, the plurality of buried contacts BC may be interposed between the plurality of bit lines BL and between the plurality of word lines WL. In some embodiments, the buried contacts BC may be arranged in a lattice structure.

The buried contact BC may include a conductive material. Accordingly, the buried contact BC may be electrically connected to the active region AR of the second substrate 100. The active region AR of the second substrate 100 that is connected to the buried contact BC may function as a source/drain region of a semiconductor element including the word line WL. The buried contact BC may include, for example, polysilicon, but the present invention is not limited thereto.

In some embodiments, the top surface of the buried contact BC may be formed to be lower than the top surface of the second bit line capping pattern 139 as illustrated in FIG. 15. For example, the top surface of the buried contact BC may be formed to be lower than the top surface of the second bit line capping pattern 139 through an etch-back process. Accordingly, the buried contacts BC forming a plurality of isolated regions may be formed. The buried contact BC may include polysilicon, but the present invention is not limited thereto. As used herein, “a surface V is lower than a surface W” (or similar language) may mean that the surface V is closer than the surface W to the second substrate 100.

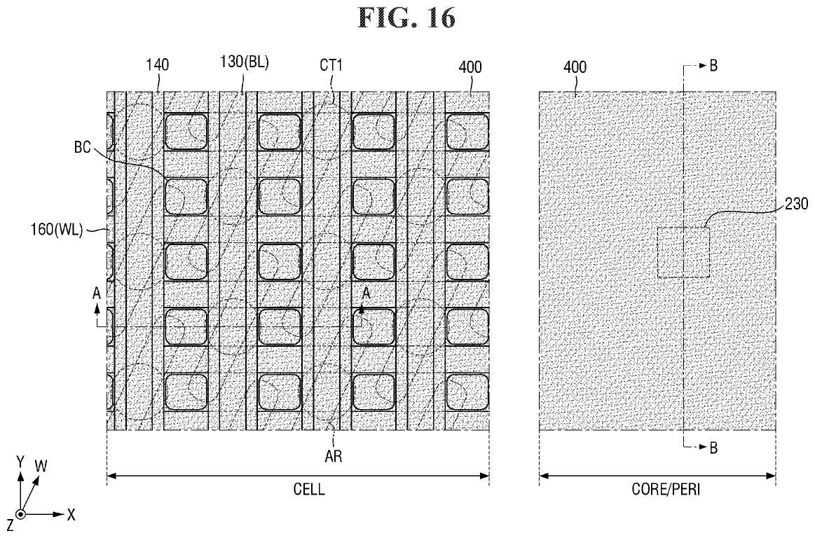

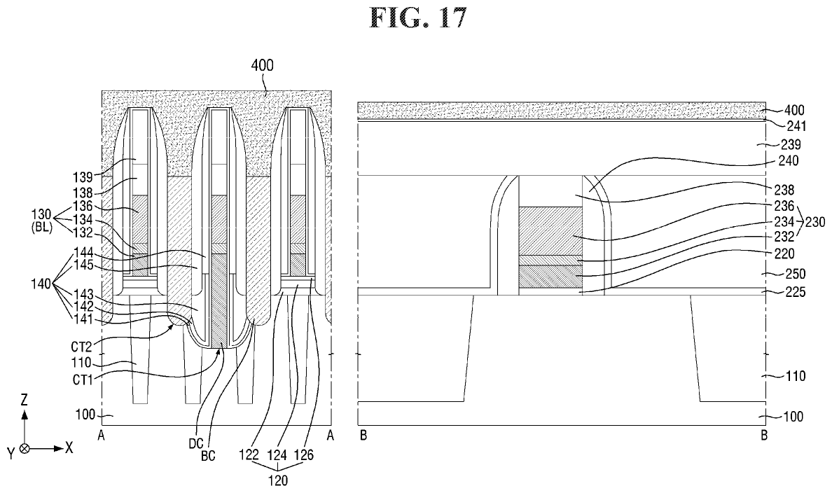

Referring to FIGS. 16 and 17, a fourth conductive layer 400 is formed on the cell area CELL and the core/peri area CORE/PERI.

For example, the fourth conductive layer 400 may be formed on the buried contact BC of the cell area CELL and the second liner layer 241 of the core/peri area CORE/PERI. The fourth conductive layer 400 may be electrically connected to the buried contact BC. The fourth conductive layer 400 may include, for example, tungsten (W), but the present invention is not limited thereto.

In some embodiments, the top surface of the fourth conductive layer 400 may be formed to be higher than the top surface of the second bit line capping pattern 139.

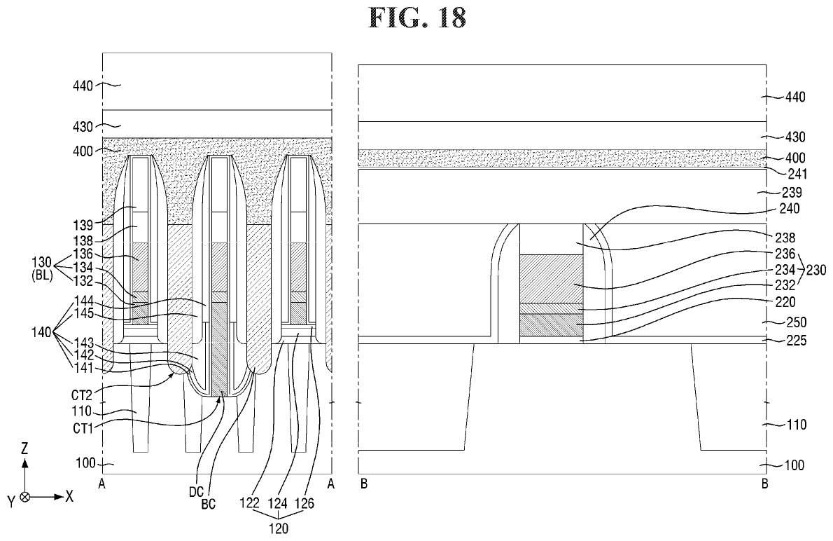

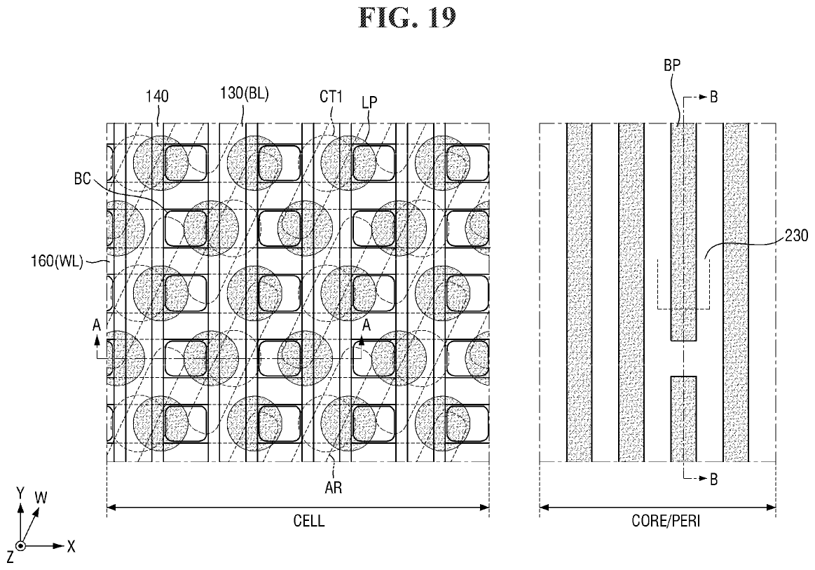

Referring to FIG. 18, a second mask layer 430 and a second photoresist layer 440 are sequentially formed on the fourth conductive layer 400.

The second mask layer 430 may be formed on a target layer (e.g., the fourth conductive layer 400). For example, the second mask layer 430 may be formed by being applied to the target layer through a spin-coating process, followed by a baking process. The second mask layer 430 may include, for example, a spin-on hardmask (SOH), but the present invention is not limited thereto.

The second photoresist layer 440 may be formed on the second mask layer 430. The second photoresist layer 440 may be formed on the second mask layer 430 through a coating process such as a spin coating, dip-coating or spray-coating process. In some embodiments, after the second photoresist layer 440 is applied on the second mask layer 430, a pre-curing process such as a soft-baking process may be performed thereon.

The second photoresist layer 440 may include the photoresist composition. For example, the second photoresist layer 440 may include the photosensitive resin, the photoacid generator, the photoacid-labile additive, and the balance of the solvent.

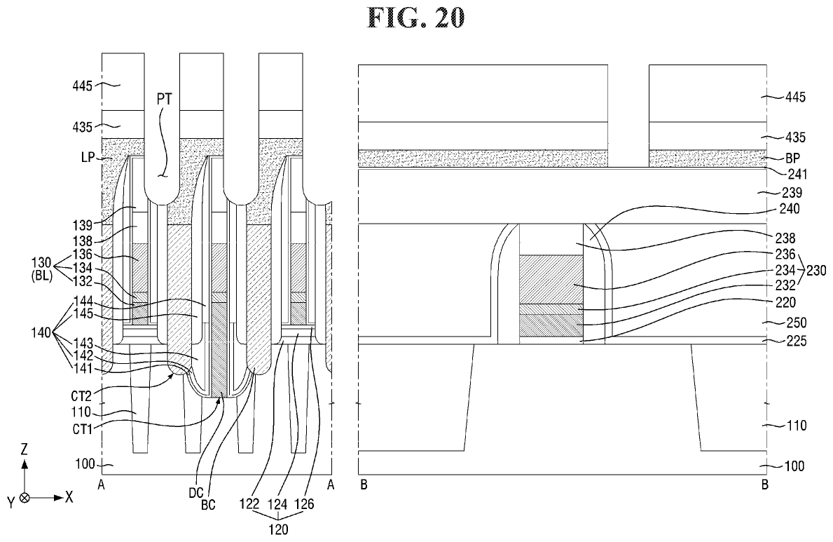

Referring to FIGS. 19 and 20, a patterning process is performed on the fourth conductive layer 400.

The patterning process may be carried out using the method for forming a pattern described with reference to FIGS. 1 to 7 above. For example, the second mask layer 430 and the fourth conductive layer 400 may be etched using the second photoresist pattern 445 as an etching mask to form a second mask pattern 435 and a landing pad LP.

A plurality of landing pads LP may be formed in a cell area CELL. For example, a pad trench PT defining the plurality of landing pads LP may be formed through the patterning process.

The landing pad LP may be formed on the buried contact BC. The landing pad LP may be disposed to overlap the buried contact BC. The term “overlapping” as used herein means overlapping in a vertical direction Z that is perpendicular to the top surface of the second substrate 100. The landing pad LP may be connected to the top surface of the buried contact BC to connect the active region AR of the second substrate 100 to the capacitor 190 to be described later. As used herein, “an element A overlapping an element B in a vertical direction Z” (or similar language) may mean that at least one vertical line can be drawn that intersects both elements A and B.

In some embodiments, the landing pad LP may be disposed to overlap a part of the buried contact BC and a part of the bit line BL. For example, the landing pad LP may overlap a part of the buried contact BC and a part of the second bit line capping pattern 139 as shown in FIG. 20. In some embodiments, the top surface of the landing pad LP may be formed to be higher than the top surface of the second bit line capping pattern 139. Accordingly, the landing pad LP may cover a part of the top surface of the second bit line capping pattern 139.

In some embodiments, a part of the pad trench PT may expose a part of the second bit line capping pattern 139. For example, the pad trench PT may be formed to extend from the top surface of the landing pad LP such that the bottom surface thereof is lower than the top surface of the second bit line capping pattern 139. Accordingly, the plurality of landing pads LP may be separated from each other by the second bit line capping pattern 139 and the pad trench PT.

In some embodiments, as shown in FIG. 19, the plurality of landing pads LP may be arranged in a honeycomb structure.

In some embodiments, the plurality of landing pads LP of the cell area CELL may be formed simultaneously along with the formation of the wiring pattern BP of the core/peri area CORE/PERI. For example, the second patterning process may include forming the wiring pattern BP by patterning the fourth conductive layer 400 of the core/peri area CORE/PERI.

The wiring pattern BP may be formed on the third conductive pattern 230. For example, the wiring pattern BP may extend along the top surface of the second interlayer insulating layer 250. In some embodiments, the wiring pattern BP may be a bypass wiring. The wiring pattern BP may include, for example, tungsten (W) or aluminum (Al), but the present invention is not limited thereto.

In some embodiments, a second liner layer 241 may be formed between the wiring pattern BP and the second interlayer insulating layer 250. The second liner layer 241 may extend along the top surface of the second interlayer insulating layer 250. The second liner layer 241 may function as an etch stop layer, but the present invention is not limited thereto. In some embodiments, the first spacer 141 and the second liner layer 241 may be formed at the same level from the second substrate 100. In some embodiments, the second liner layer 241 may be formed between the wiring pattern BP and the third interlayer insulating layer 239 and may contact the top surface of the third interlayer insulating layer 239 as illustrated in FIG. 20. In some embodiments, upper surfaces of the first spacer 141 and the second liner layer 241 may be at the same level from the second substrate 100.

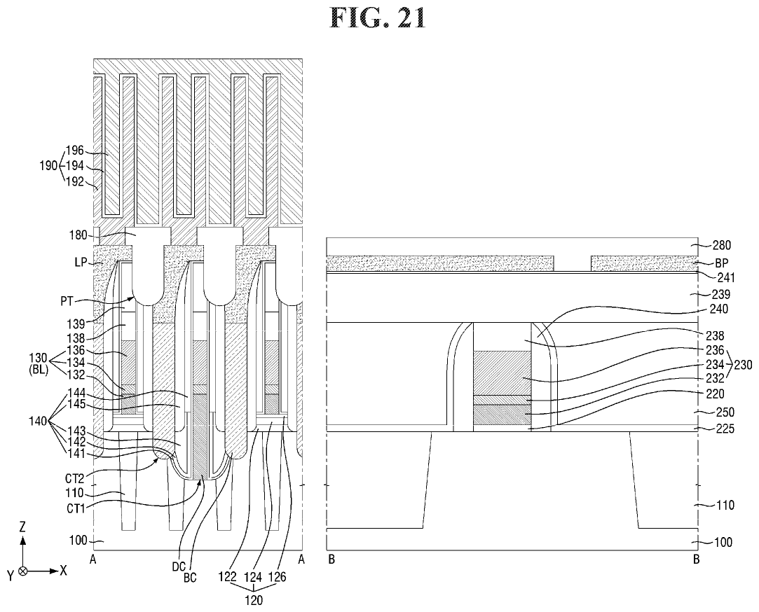

Then, referring to FIG. 21, the first interlayer insulating layer 180 is formed on the landing pad LP.

For example, the first interlayer insulating layer 180 for filling the pad trench PT may be formed. Accordingly, the plurality of landing pads LP forming the plurality of isolated regions separated from each other by the first interlayer insulating layer 180 may be formed. In some embodiments, the first interlayer insulating layer 180 may be patterned to expose at least a part of the top surface of each landing pad LP.

Then, a lower electrode 192 connected to the landing pad LP exposed by the first interlayer insulating layer 180 may be formed. Then, a capacitor dielectric layer 194 and an upper electrode 196 may be sequentially formed on the lower electrode 192. Accordingly, a capacitor 190 connected to the landing pad LP may be formed.

A fourth interlayer insulating layer 280 may be formed on the wiring pattern BP. The fourth interlayer insulating layer 280 may be formed to cover the top surface of the wiring pattern BP. In some embodiments, the fourth interlayer insulating layer 280 and the first interlayer insulating layer 180 may be formed at the same level. In some embodiments, the fourth interlayer insulating layer 280 and the first interlayer insulating layer 180 may be formed by same processes (e.g., a deposition process and an etching process).

As described above, the methods for fabricating a semiconductor device according to some embodiments may be carried out using the photoresist composition including the photoacid-labile additive. Accordingly, a method for fabricating a semiconductor device with improved reliability and productivity may be provided.

Hereinafter, effects of the photoresist compositions according to some embodiments will be described with reference to the following experimental examples and comparative examples.

### Experimental Example 1

A photoresist composition was prepared using poly(hydroxystyrene-co-propylcyclopentylmethacrylate) as the photosensitive resin, using triphenylsulfonium difluoromethylsulfonate as the photoacid generator, using ethoxymethyl 4-(trifluoromethyl)benzoate as the photoacid-labile additive, and using propylene glycol methyl ether acetate and propylene glycol methyl ether as the solvent.

The poly(hydroxystyrene-co-propylcyclopentylmethacrylate) was used in an amount of 1.05 parts by weight with respect to 100 parts by weight of the photoresist composition. The triphenylsulfonium difluoromethylsulfonate and the ethoxymethyl 4-(trifluoromethyl)benzoate were used in amounts of 0.3 parts by weight and 0.05 parts by weight, respectively, with respect to 1 part by weight of the poly(hydroxystyrene-co-propylcyclopentylmethacrylate).

### Experimental Example 2

A photoresist composition was prepared in a similar manner to in Experimental Example 1, except that 1,4-di-((tert-butyloxycarbonyl)oxy)-benzene was used as the photoacid-labile additive.

### Comparative Example 1

A photoresist composition was prepared in a similar manner to in Experimental Example 1, except that the photoacid-labile additive was not used.

### Comparative Example 2

A photoresist composition was prepared in a similar manner to in Experimental Example 1, except that 4-(trifluoromethyl)benzoic acid was used as the photoacid-labile additive.

Evaluation of Defect and Distribution

Semiconductor devices were fabricated using the photoresist compositions according to Experimental Examples 1 and 2 and Comparative Examples 1 and 2. The fabrication of the semiconductor devices was carried out using the method for fabricating a semiconductor device described with reference to FIGS. 8 to 21 above. The critical dimension of the landing pattern LP was set to 27 nm, and the critical dimension of the wiring pattern BP was set to 25 nm. Subsequently, defects and distribution of the fabricated semiconductor devices were evaluated, and are shown in Table 1 below.

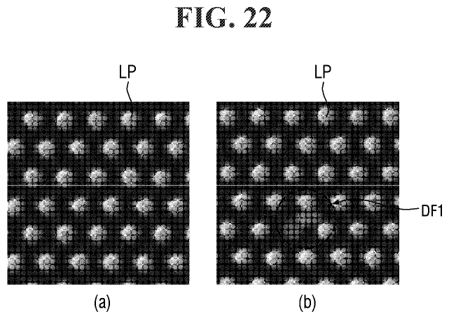

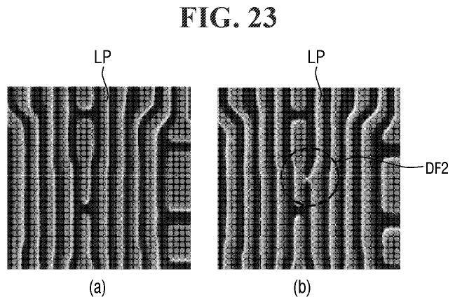

The defect was measured as the sum of the number of defects of the landing pattern LP per unit chip and the number of defects of the wiring pattern BP per unit chip. For example, referring to FIG. 22, the landing pattern LP may include a first defect DF1. In addition, for example, referring to FIG. 23, the wiring pattern BP may include the second defect DF2.

The distribution was determined by measuring the depth of focus (DOF) of the photography process.

TABLE 1

| | light dose | | |
|---|---|---|---|
| | (mJ/cm²) | defect (EA) | DOF (nm) |
| Experimental | 33 | 16.9 | 60 |
| Example 1 | | | |
| Experimental | 91 | 34 | 60 |
| Example 2 | | | |
| Comparative | 34 | 46.2 | 45 |
| Example 1 | | | |
| Comparative | 88 | 107 | 60 |
| Example 2 | | | |

As can be seen from Table 1 above, the semiconductor device fabricated using the photoresist composition prepared according to Experimental Example 1 exhibits remarkably reduced defects and improved distribution at a similar light dose, compared to the semiconductor device fabricated using the photoresist composition prepared according to Comparative Example 1. In addition, as can be seen from Table 1 above, the semiconductor device fabricated using the photoresist composition prepared according to Experimental Example 2 exhibits remarkably reduced defects at a similar light dose, compared to the semiconductor device fabricated using the photoresist composition prepared according to Comparative Example 2.

Accordingly, the photoresist compositions according to some embodiments are capable of providing a method for fabricating semiconductor devices having improved reliability and productivity by improving the quality of photoresist patterns.

While the present invention has been particularly shown and described with reference to some example embodiments thereof, it will be understood by those of ordinary skill in the art that various changes in form and details may be made therein without departing from the scope of the present invention as defined by the following claims. It is therefore desired that the present embodiments be considered in all respects as illustrative and not restrictive, reference being made to the appended claims rather than the foregoing description to indicate the scope of the invention.

1. A photoresist composition comprising:
a photosensitive resin;
a photoacid generator; and
a photoacid-labile additive comprising a structure of Formula 1-1:
Ar²—Y—PG² [Formula 1-1]
wherein Ar² is a substituted or unsubstituted aromatic ring,
Y is an ester group, an oxycarbonyl group, an acetal group, an amide group, or a thioester group, and
PG² is a substituted or unsubstituted secondary alkyl group, a substituted or unsubstituted tertiary alkyl group, a substituted or unsubstituted alkoxyalkyl group, a substituted or unsubstituted alkoxy group, or a substituted or unsubstituted alkyloxycarbonyl group.

2. The photoresist composition of claim 1, wherein the photoacid-labile additive comprises a structure of Formula 1-2 or Formula 1-3:
EWG-Ar²—Y—PG² [Formula 1-2]
wherein EWG is an electron withdrawing group,
PG²-Y—Ar²—Y—PG² [Formula 1-3]

3. The photoresist composition of claim 2, wherein the photoacid-labile additive has a structure of Formula 2 or Formula 3:

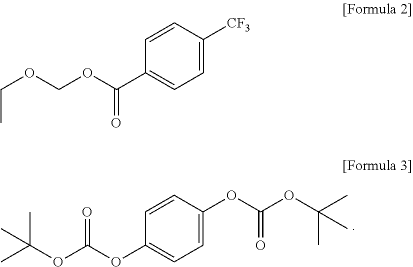 [SMILES: CCOCOC(=O)c1ccc(C(F)(F)F)cc1 ; CC(C)(C)OC(=O)Oc1ccc(OC(=O)OC(C)(C)C)cc1]

4. The photoresist composition of claim 1, wherein the photosensitive resin has a structure of Formula 2: 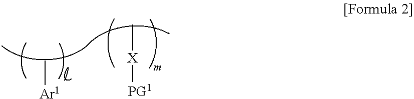
Wherein [symbol] and m are each a natural number,
Ar¹ is a substituted or unsubstituted aromatic ring,
X is a first photoacid-labile group comprising a first hydrophilic functional group that is configured to be exposed by a photoacid that is generated from the photoacid generator, and
PG¹ is a first protecting group that is configured to be removed by the photoacid.

5. (canceled)

6. The photoresist composition of claim 1, wherein the photoresist composition comprises the photoacid-labile additive in a range of 0.05 parts by weight to 0.15 parts by weight with respect to 1 part by weight of the photosensitive resin.

7. The photoresist composition of claim 1, wherein the photoresist composition comprises the photoacid generator in a range of 0.3 parts by weight to 0.4 parts by weight with respect to 1 part by weight of the photosensitive resin.

8. The photoresist composition of claim 1, wherein the photoresist composition comprises the photosensitive resin in a range of 1 part by weight to 4 parts by weight with respect to 100 parts by weight of the photoresist composition.

9. A photoresist composition comprising:
a photosensitive resin comprising a structure of Formula 1;
a photoacid generator configured to generate a photoacid in response to exposure to a light source; and
a photoacid-labile additive comprising a structure of Formula 2-1 or Formula 2-2: 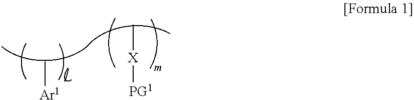
wherein [symbol] and m are each a natural number,
Ar¹ is a substituted or unsubstituted aromatic ring,
X is a first photoacid-labile group comprising a first hydrophilic functional group that is configured to be exposed by the photoacid, and
PG¹ is a first protecting group that is configured to be removed by the photoacid,
EWG-Ar²—Y—PG² [Formula 2-1]
PG²-Y—Ar²—Y—PG² [Formula 2-2]
wherein Ar² is a substituted or unsubstituted aromatic ring,
Y is a second photoacid-labile group comprising a second hydrophilic functional group that is configured to be exposed by the photoacid,
PG² is a second protecting group that is configured to be removed by the photoacid, and
EWG is an electron withdrawing group.

10. The photoresist composition of claim 9, wherein X is an ester group, and
PG¹ is a substituted or unsubstituted secondary alkyl group, a substituted or unsubstituted tertiary alkyl group, a substituted or unsubstituted alkoxyalkyl group, a substituted or unsubstituted alkoxy group, or a substituted or unsubstituted alkyloxycarbonyl group.

11. The photoresist composition of claim 10, wherein Ar¹ is a 4-hydroxyphenyl group.

12. The photoresist composition of claim 9, wherein Y is an ester group, an oxycarbonyl group, or an acetal group, and
PG² is a substituted or unsubstituted secondary alkyl group, a substituted or unsubstituted tertiary alkyl group, a substituted or unsubstituted alkoxyalkyl group, a substituted or unsubstituted alkoxy group, or a substituted or unsubstituted alkyloxycarbonyl group.

13. The photoresist composition of claim 12, wherein Ar² is a p-phenylene group.

14. The photoresist composition of claim 9, wherein the photoresist composition comprises the photosensitive resin in a range of 1 part by weight to 4 parts by weight with respect to 100 parts by weight of the photoresist composition,
the photoacid generator in a range of 0.3 parts by weight to 0.4 parts by weight with respect to 1 part by weight of the photosensitive resin, and
the photoacid-labile additive in a range of 0.05 parts by weight to 0.15 parts by weight with respect to 1 part by weight of the photosensitive resin.

15. The photoresist composition of claim 14, further comprising a sensitizer that is configured to amplify an amount of photons emitted from the light source,
wherein the photoresist composition comprises the sensitizer in a range of 0.3 parts by weight to 0.4 parts by weight with respect to 1 part by weight of the photosensitive resin.

16. A photoresist composition comprising:
a photoacid generator configured to generate a photoacid in response to exposure to a light source;
a photosensitive resin including a substituted or unsubstituted first aromatic ring, a first photoacid-labile group comprising a first hydrophilic functional group that is configured to be exposed by the photoacid, and a first protecting group that is bonded to the first photoacid-labile group and is configured to be removed by the photoacid; and
a photoacid-labile additive including a substituted or unsubstituted second aromatic ring, a second photoacid-labile group comprising a second hydrophilic functional group that is configured to be exposed by the photoacid, and a second protecting group that is bonded to the second photoacid-labile group and is configured to be removed by the photoacid,
wherein the first hydrophilic functional group and the second hydrophilic functional group are configured to form a non-covalent bond.

17. The photoresist composition of claim 16, wherein the first photoacid-labile group and the second photoacid-labile group each independently include an ester group, an oxycarbonyl group, an acetal group and/or an amide group.

18. The photoresist composition of claim 16, wherein the first hydrophilic functional group and the second hydrophilic functional group each independently include a hydroxy group and/or a carboxyl group.

19. The photoresist composition of claim 16, wherein the first protecting group and the second protecting group each independently include a substituted or unsubstituted secondary alkyl group, a substituted or unsubstituted tertiary alkyl group, a substituted or unsubstituted alkoxyalkyl group and/or a substituted or unsubstituted alkoxy group.

20. The photoresist composition of claim 16, wherein the non-covalent bond includes a hydrogen bond.

21. The photoresist composition of claim 16, wherein the first aromatic ring and the second aromatic ring form a π bond.

22-24. (canceled)
